(19) United States
(12) Patent Application Publication
(10) Pub. No.: US 2001/0032705 A1
(43) Pub. Date: Oct. 25, 2001

(54) LOCAL ETCHING APPARATUS AND LOCAL ETCHING METHOD

(76) Inventors: TAKESHI SADOHARA, AYASE-SHI (JP); MICHIHIKO YANAGISAWA, AYASE-SHI (JP); SHINYA IIDA, AYASE-SHI (JP); YASUHIRO HORIIKE, HOUYA-SHI (JP)

Correspondence Address: BURR & BROWN, PO BOX 7068, SYRACUSE, NY, 13261-7068, US

(21) Appl. No.: 09/362,760

(22) Filed: Jul. 28, 1999

(30) Foreign Application Priority Data
Oct. 21, 1998 (JP) 10-299600

(51) Int. Cl. H01L 21/311

(52) U.S. Cl. 156/345; 438/715

(57) ABSTRACT

A local etching apparatus and a local etching method provide a high etching rate without impairing the mirror surface of the object to be etched and free from unevenness of the etching rate, thereby enabling the entire surface of an object to be etched to be etched by a uniform etching rate. The local etching apparatus includes a plasma generator 1 to cause plasma discharge of a mixed gas of CF₄ and O₂ fed from a gas feeder 3 to an alumina discharge tube 2 to produce F radicals R and spraying the F radicals R from the nozzle portion 20 to a silicon wafer W on a chuck 93 so as to locally etch the silicon wafer W. At this time, a power supply 71 of a wafer heating portion 7 is turned on and a voltage adjusted by a voltage regulator 72 is supplied to a spiral-shaped heating wire 70 in the chuck 93 to heat the entire silicon wafer W to, preferably, a heating temperature of the silicon wafer W set to a temperature range of from 20° C. to 300° C.

### BACKGROUND OF THE INVENTION

1. Field of the Invention

The present invention relates to a local etching apparatus and a local etching method for spraying radicals produced by plasma discharge from a nozzle to a silicon wafer or other object to be etched to locally etch the object to be etched.

2. Description of the Related Art

FIG. 15 is a schematic sectional view of a local etching apparatus of the related art.

This local etching apparatus causes plasma discharge of carbon tetrafluoride (CF₄) gas etc. by a plasma generator 100 to produce fluorine (F) radicals and other radicals and sprays the F radicals R from a nozzle portion 110 to the surface Wa of a silicon wafer W on a stage 120 to locally etch portions thicker than a reference thickness value among the portions of the surface Wa (hereinafter called “relatively thick portions”). Specifically, it reduces the speed of movement of the stage 120, that is, the relative speed of the nozzle portion 110, to prolong the time of spraying the F radicals R over the thicker relatively thick portions Wb and increases the relative speed of the nozzle portion 110 to shorten the time of spraying the F radicals R over the thinner relatively thick portions Wb and thereby flatten the surface Wa of the silicon wafer W as a whole.

In this local etching apparatus of the related art, however, there was the following problem.

A local etching apparatus generally uses CF₄ gas and produces F radicals R by causing plasma discharge of the CF₄ gas. Since the amount of the F radicals R produced, however, is small, the etching rate of the silicon wafer W is small and the throughput is low.

To deal with this, a local etching apparatus designed to improve the etching rate by using sulfur hexafluoride (SF₆) gas, which produces a greater amount of F radicals R, has been proposed. If SF₆ gas is used to etch a silicon wafer W, however, white turbidity occurs at the surface Wa of the silicon wafer W and the mirror surface ends up being damaged.

Further, both a local etching apparatus using CF₄ gas and a local etching apparatus using SF₆ gas suffer from the problem of a lower etching rate at the outer circumference of the silicon wafer W compared with the etching rate at the center.

### SUMMARY OF THE INVENTION

The present invention was made to solve the above problems and has as its object the provision of a local etching apparatus and local etching method giving a high etching rate without impairing the mirror surface of the object to be etched and free from unevenness of the etching rate, thereby enabling the entire surface of an object to be etched to be etched by a uniform etching rate.

To achieve the above object, according to a first aspect of the present invention, there is provided a local etching apparatus comprising: a plasma generating means for causing plasma discharge of a predetermined gas in a discharge tube to produce radicals and spraying the radicals from a nozzle portion of the discharge tube toward a relatively thick portion present on the surface of an object to be etched; a gas feeding means for feeding the predetermined gas to the discharge tube of the plasma generating means; and a heating means for heating the object to be etched to a predetermined temperature.

Due to this configuration, by using the gas feeding means to feed a predetermined gas to the discharge tube and using the plasma generating means to cause plasma discharge of the predetermined gas in the discharge tube and spray the produced radicals from the nozzle portion toward a relatively thick portion of the surface of the object to be etched, it is possible to locally etch the relatively thick portion. At this time, by using the heating means to heat the object to be etched to a predetermined temperature, the reaction between the radicals and object to be etched is promoted and the etching rate is improved. Further, since the object to be etched is being heated, even if SF₆ gas etc. is used, there is almost no white turbidity etc. produced at the surface of the object to be etched.

Here, the object to be etched may be heated by full heating and partial heating. One is free to use either method of heating. Therefore, as an example of full heating, according to an embodiment of the invention, the heating means is designed to heat the entire object to be etched to a substantially uniform temperature.

As an example of the heating means for full heating, according to an embodiment of the invention, the heating means is provided with an electrical heating member arranged facing substantially the entire surface of the back of the object to be etched and capable of being raised in temperature in accordance with the voltage supplied and a voltage controller for controlling the voltage supplied to the electrical heating member.

Various heating means may be considered for supplying voltage to the electrical heating member to generate heat and uniformly heat the object to be etched as a whole, but as a specific example, according to an embodiment of the invention, the heating means is a heater and the electrical heating member is a heating wire bent into a spiral or grid along substantially the entire surface of the back of the object to be etched.

As another example of the heating means for full heating, according to an embodiment of the invention, the heating means is an optical heating means which irradiates infrared light or a laser beam on substantially the entire surface of the front or back of the object to be etched to heat the object to be etched.

Further, as an example of partial heating, according to an embodiment of the invention, the heating means is designed to heat the object to be etched so that the temperature of the outer circumference of the object to be etched becomes higher than the temperature of the center of the object to be etched by exactly a predetermined temperature so as to make the etching rate of the outer circumference of the object to be etched and the etching rate of the rest of the portions of the object to be etched substantially equal.

Due to this configuration, it is possible to solve the problem of the related art of the etching rate of the outer circumference of the object to be etched tending to become lower than that of the other portions and therefore possible to improve the flatness of the object to be etched as a whole.

Further, as an example of the heating means for the partial heating, according to an embodiment of the invention, the heating means is provided with an electrical heating member arranged to face the outer circumference of the back of the object to be etched and capable of being raised in temperature in accordance with the voltage supplied and a voltage controller for controlling the voltage supplied to the electrical heating member.

Various heating means may be considered for supplying voltage to the electrical heating member to generate heat and uniformly heat the outer circumference of the object to be etched to a temperature higher than the other portions but as a specific example, according to an embodiment of the invention, the heating means is a heater and the electrical heating member is a heating wire bent into a spiral or grid along the outer circumference of the back of the object to be etched.

As another example of the heating means for partial heating, according to an embodiment of the invention, the heating means is an optical heating means which irradiates infrared light or a laser beam on the outer circumference of the front of the object to be etched to heat the object to be etched.

As a preferred example of the heating temperature of the object to be etched, according to an embodiment of the invention, the heating temperature of the object to be etched is a temperature in the range of from 20° C. to 300° C.

Further, as a preferred example of the object to be etched and preferred example of the gas for plasma discharge, according to an embodiment of the invention, the object to be etched is a silicon wafer and the predetermined gas which the gas feeding means supplies to the discharge tube is a gas selected from the group consisting of carbon tetrafluoride gas, sulfur hexafluoride gas, nitrogen trifluoride gas and a mixed gas containing at least one of these gases.

The process of operation executed by the local etching apparatus stands as a process invention as well.

Therefore, according to a second aspect of the invention, there is provided a local etching method comprising: a plasma generating step of causing plasma discharge of a predetermined gas in a discharge tube to produce radicals and spraying the radicals from a nozzle portion of the discharge tube; a local etching step of making the nozzle portion of the discharge tube move relative to the surface of the object to be etched and locally etch a relatively thick portion present on the surface of the object to be etched by the radicals sprayed from the nozzle portion; and a heating step of heating the object to be etched to a predetermined temperature.

Further, according to an embodiment of the invention, the heating step is designed to heat the object to be etched so that the object to be etched as a whole becomes a substantially uniform temperature. Alternatively, according to an embodiment of the invention, the heating step heats the object to be etched so that the temperature of the outer circumference of the object to be etched becomes higher than the temperature of the center of the object to be etched by exactly a predetermined temperature so as to make the etching rate of the outer circumference of the object to be etched and the etching rate of the rest of the portions of the object to be etched substantially equal. Further, according to an embodiment of the invention, the heating step heats the object to be etched to a temperature in the range of from 20° C. to 300° C. Further, according to an embodiment of the invention, the object to be etched is a silicon wafer and the predetermined gas in the discharge tube in the plasma generating step is a gas selected from the group consisting of carbon tetrafluoride gas, sulfur hexafluoride gas, nitrogen trifluoride gas and a mixed gas containing at least one of these gases.

### BRIEF DESCRIPTION OF THE DRAWINGS

The above and other objects, features, and advantages of the present invention will become more readily apparent from the following detailed description of a presently preferred embodiment of the invention taken in conjunction with the accompanying drawings, in which:

FIG. 1 is a schematic sectional view of a local etching apparatus according to a first embodiment of the present invention;

FIG. 2 is a schematic sectional view of the shape of a heating wire of a wafer heating portion;

FIG. 3 is a graph of the relationship between a heating temperature and a maximum amount of etching in the case of use of CF₄ gas;

FIG. 4 is a graph of the relationship between a heating temperature and a maximum amount of etching in the case of use of SF₆ gas;

FIG. 5 is a schematic sectional view of essential portions of a local etching apparatus according to a second embodiment of the present invention;

FIG. 6 is a schematic side sectional view of the state of etching of the silicon wafer;

FIG. 7 is a partially sectional view of the residual state of the outer circumference of the silicon wafer at the time of ordinary temperature;

FIG. 8 is a partially sectional view of the state of flattening of the silicon wafer at the time of heating;

FIG. 9 is a schematic sectional view of a modification of the heating wire for full heating;

FIG. 10 is a schematic sectional view of a modification of the electrical heating member for full heating;

FIG. 11 is a schematic sectional view of a modification of the heating wire for partial heating;

FIG. 12 is a schematic sectional view of a modification of the electrical heating member for partial heating;

FIG. 13 is a schematic sectional view of a first modification of a wafer heating portion;

FIG. 14 is a schematic sectional view of a second modification of a wafer heating portion; and

FIG. 15 is a schematic sectional view of an example of a local etching apparatus of the related art.

### DESCRIPTION OF THE PREFERRED EMBODIMENTS

Preferred embodiments of the present invention will be explained next with reference to the drawings.

(First Embodiment)

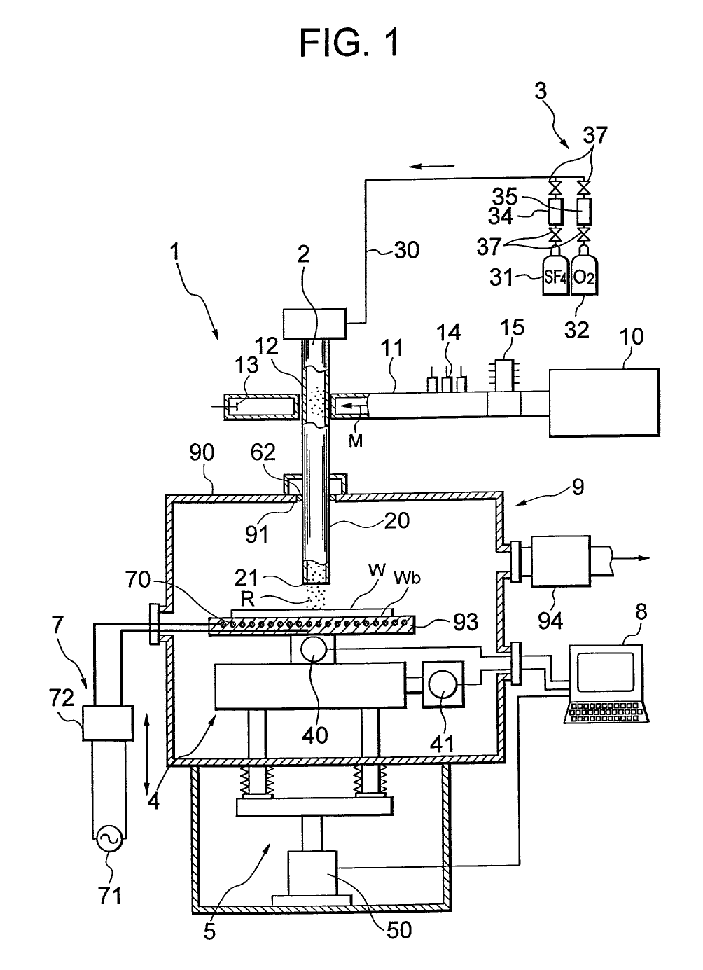

FIG. 1 is a schematic sectional view of a local etching apparatus according to a first embodiment of the present invention.

The local etching apparatus is provided with a plasma generator 1 as a plasma generating means, an alumina discharge tube 2, a gas feeder 3 as a gas feeding means, an X-Y drive 4, a Z-drive 5, and a wafer heating portion 7 as a heating means.

The plasma generator 1 is a device for causing plasma discharge of gas inside the alumina discharge tube 2 to produce radicals and is comprised of a microwave generator 10 and a waveguide 11.

The microwave generator 10 is a magnetron and can generate a microwave M of a predetermined frequency.

The waveguide 11 is for guiding the microwave M generated by the microwave generator 10 and is fit over the alumina discharge tube 2 through a hole 12.

At the inside of the left end of the waveguide 11 is attached a reflection plate (short plunger) 13 for reflecting the microwave M to form a standing wave. Further, in the middle of the waveguide 11 are attached a 3-stub tuner 14 for positioning the microwave M and an isolator 15 for bending the reflected microwave M heading toward the microwave generator 10 90° in direction (surface direction of FIG. 1).

The alumina discharge tube 2 is a cylinder having a nozzle portion 20 at its lower end, passes through the upper wall 90 of a chamber 9, and has a spray port 21 facing the front surface of the silicon wafer W.

Specifically, a hole 91 is made at the center of the upper wall 90 of the chamber 9. The nozzle portion 20 of the alumina discharge tube 2 is inserted into the chamber 9 through this hole 91. An O-ring 92 is fit between the hole 91 and the alumina discharge tube 2 so as to keep the space between the hole 91 and the alumina discharge tube 2 airtight.

At the upper end of this alumina discharge tube 2 is connected a feed pipe 30 of the gas feeder 3.

The gas feeder 3 is a device for feeding gas into the alumina discharge tube 2 and has a CF₄ (carbon tetrachloride) gas cylinder 31 and an O₂ (oxygen) gas cylinder 32. The gas cylinders 31, 32 are connected to the feed pipe 30 through valves 37 and flow controllers 34, 35.

By adopting this configuration for the plasma generator 1, a mixed gas of CF₄ and O₂ is fed from the gas feeder 3 to the alumina discharge tube 2, plasma discharge is caused upon generation of the microwave M from the microwave generator 10, and F radicals R produced by the plasma discharge are sprayed from the spray port 21 of the nozzle portion 20.

The X-Y drive 4 is arranged inside the chamber 9 and supports a chuck 93 from below.

The X-Y drive 4 makes the chuck 93 move in the lateral direction in FIG. 1 by an X-drive motor 40 and makes the chuck 93 and the X-drive motor 40 move in the direction perpendicular to the surface of the paper on which FIG. 1 is drawn by a Y-drive motor 41. That is, it is possible to make the nozzle portion 20 move in the X-Y direction relative to the silicon wafer W by the X-Y drive 4.

The drive operations of the X-drive motor 40 and Y-drive motor 41 of the X-Y drive 4 are controlled by a control computer 8 based on a predetermined program.

The chamber 9 as a whole is designed to be able to move vertically with respect to the alumina discharge tube 2. The Z-drive 5 supports the chamber 9 from below. The Z-drive 5 makes the chamber 9 as a whole move in the vertical direction by a Z-drive motor 50 and enables the distance between the spray port 21 of the nozzle portion 20 and the surface of the silicon wafer W to be adjusted.

Note that reference numeral 94 in FIG. 1 is a vacuum pump. This vacuum pump 94 may be used to create a state of vacuum inside the chamber 9.

The wafer heating portion 7 is a heater for heating the silicon wafer W as a whole to a substantially uniform temperature and is comprised of a heating wire 70 as the electrical heating member, a power supply 71 for supplying voltage to the heating wire 70, and a voltage regulator 72 for controlling the voltage supplied from the power supply 71 to the heating wire 70 and constituting a voltage controller together with the power supply 71.

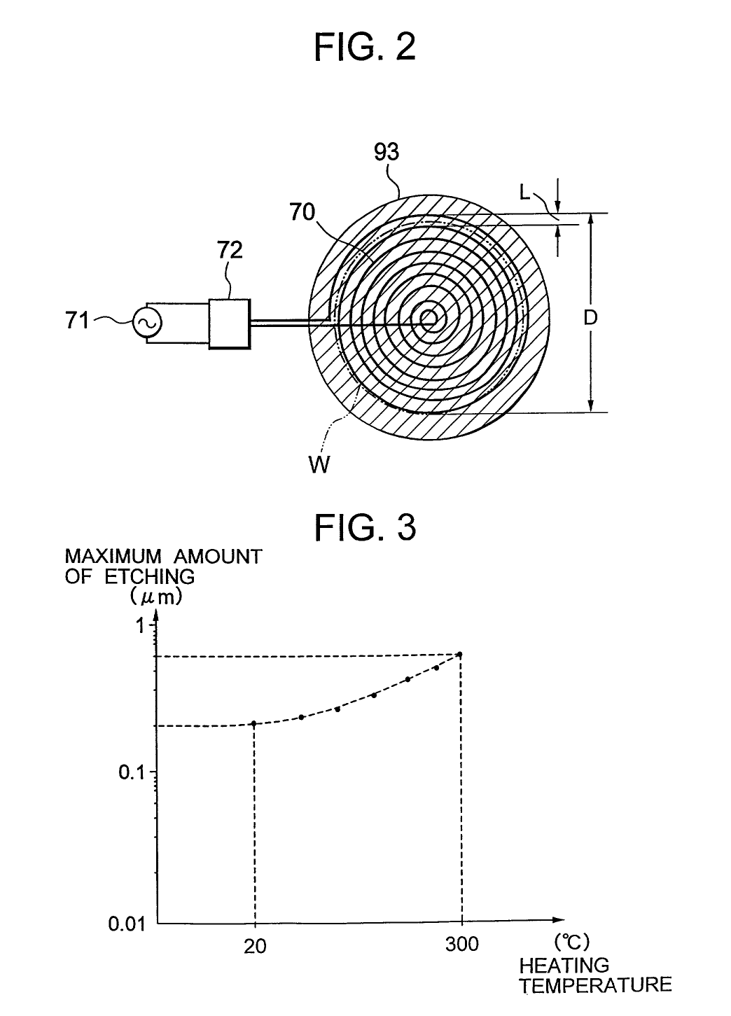

The heating wire 70, as shown in FIG. 2, is bent in a spiral at a predetermined wire interval L. The diameter D of the spiral is set to be somewhat larger than the diameter of the silicon wafer W (shown by two-dot broken line).

This heating wire 70, as shown in FIG. 1, is accommodated in the chuck 93 and faces the entire surface of the back Wb of the silicon wafer W placed on the chuck 93. That is, the heating wire 70 is arranged below the silicon wafer W in a state bent into a spiral along the entire surface of the back Wb of the silicon wafer W.

The two ends of the heating wire 70 are led out from the chuck 93 and electrically connected to the voltage regulator 72 at the outside of the chamber 9. The voltage regulator 72 is electrically connected to the power supply 71.

Due to this, by turning the power supply 71 on and adjusting the voltage regulator 72 to control the voltage supplied to the heating wire 70, the heating wire 70 is heated to a temperature corresponding to the voltage supplied. The heat of the heating wire 70 is conducted to the chuck 93 as a whole, and the silicon wafer W as a whole is heated to a uniform temperature.

Next, an explanation will be given of the operation of the local etching apparatus of this embodiment. Note that since it is possible to execute the local etching method according to the aspect of the present invention by operating the local etching apparatus, the explanation will be given along with the steps of that method.

First, the plasma generation step is executed.

That is, in FIG. 1, the vacuum pump 94 is driven in the state with the silicon wafer W held by suction against the chuck 93 so as to bring the inside of the chamber 9 to a low air pressure state of 0.1 Torr to 5.0 Torr and the Z-drive 5 is driven to raise the chamber 9 as a whole so as to bring the silicon wafer W close to the nozzle portion 20.

In this state, the valves 37 of the gas feeder 3 are opened, the CF₄ gas and O₂ gas inside the gas cylinders 31, 32 are made to flow into the feed pipe 30, and the mixed gas of the two is fed into the alumina discharge tube 2.

At this time, the opening degrees of the valves 37 are adjusted to maintain the CF₄ gas and O₂ gas at predetermined pressures and the flow controllers 34, 35 are used to adjust the flow rate of the CF₄ gas and O₂ gas.

In parallel with the feeding of the CF₄ gas and O₂ gas, the microwave generator 10 is driven. The microwave M causes plasma discharge of the CF₄ gas present at the discharge position and production of F radicals R. Due to this, the F radicals R are guided into the nozzle portion 20 of the alumina discharge tube 2 and sprayed from the spray port 21 of the nozzle portion 20 to the silicon wafer W side.

The heating step is performed in parallel with this plasma generating step.

That is, the power supply 71 of the wafer heating portion 7 is turned on and the voltage supplied by to the heating wire 70 is controlled by the voltage regulator 72 to raise the temperature of the heating wire 70 to a temperature in the range of from 20° C. to 300° C., heat the silicon wafer W on the chuck 93 as a whole, and maintain the silicon wafer W as a whole at a uniform temperature.

The local etching step is executed in this state.

That is, the chuck 93 is made to move zigzag in the X-Y direction to make the nozzle portion 20 scan the silicon wafer W in a zigzag pattern. At this time, the relative speed of the nozzle portion 20 with respect to the silicon wafer W is set so as to be substantially inversely proportional to the thickness of the relatively thick portion to determine the etching time of the relatively thick portion of the silicon wafer W and shave flat the relatively thick portion.

The etching action of the F radicals R on the silicon wafer W is performed by the F radicals R reacting with the silicon of the silicon wafer W and the resultant silicon fluoride becoming disassociated from the silicon wafer W. Therefore, the etching rate differs depending on how much F radicals R the gas to be made to plasma discharge produces. From this viewpoint, CF₄ gas has a low amount of production of F radicals R and thereby can be said to give a low etching rate. Since the silicon wafer W as a whole is heated in the above way, however, the reaction rate of the F radicals R and silicon increases and thereby the etching rate is improved in accordance with the heating temperature. As a result, the etching rate by the local etching apparatus of this embodiment becomes extremely larger than the etching rate in the case of etching without heating such as with the local etching apparatus of the above related art.

Therefore, in the local etching apparatus of this embodiment, it may be considered to use SF₆ gas so as to further improve the etching rate, but deposits are liable to form on the surface of the silicon wafer W. Since the silicon wafer W is heated, however, the deposits immediately evaporate as soon as they deposit on the silicon wafer W and therefore the surface of the silicon wafer W becomes a mirror surface with no white turbidity at the end of the work.

Thus, the local etching step is completed by etching the entire surface of the silicon wafer W.

In this way, according to the local etching apparatus of this embodiment, since it is possible to etch a silicon wafer W heated by the wafer heating portion 7 by F radicals R, it is possible to raise the etching rate of the silicon wafer W and improve the throughput. Further, it is possible to produce a silicon wafer W with a good mirror surface free from white turbidity even when using SF₆ gas.

The present inventors conducted the following experiments to provide evidence of this point.

First, in a first experiment, they used the flow controllers 34, 35 of the gas feeder 3 to adjust the flow rates of the CF₄ gas and the O₂ gas to 600 sccm and 36 sccm, respectively, to feed a mixed gas comprised of 6 percent of O₂ with respect to CF₄ to the alumina discharge tube 2 at approximately 1 Torr and sprayed the produced F radicals R from the nozzle portion 20. They used, as a silicon wafer W, a silicon wafer W of a diameter of 200 mm and moved the nozzle portion 20 spraying the F radicals R at a relative speed of 10 mm/s with respect to the silicon wafer W for the etching. They performed the etching on seven silicon wafers W during which they adjusted the voltage regulator 72 of the wafer heating portion 7 to make the heating temperatures of the silicon wafers W different. The range of temperature change was 20° C. to 300° C. They measured the largest values of the amounts of etching of the silicon wafers W heated at the different temperatures and graphed out the results to obtain the results shown in FIG. 3.

FIG. 3 is a graph of the relationship between the heating temperature and the maximum amount of etching.

As shown in FIG. 3, the amount of etching at 20° C., that is, ordinary temperature, was about 0.2 μm, but the amount of etching rose along with the heating temperature and reached as high as about 0.5 μm at 300° C. As will be clear from the results of the experiment, even when using CF₄ gas, by raising the heating temperature, it is possible to obtain an etching rate incomparably larger than the etching rate at ordinary temperature.

Next, the inventors conducted a second experiment.

In the second experiment, they used as the gas for plasma discharge a mixed gas comprised of SF₆ and O₂. Specifically, they adjusted the flow rates of the SF₆ gas and O₂ gas to 200 sccm and 20 sccm, respectively, to feed a mixed gas comprised of 10 percent O₂ with respect to the SF₆ to the alumina discharge tube 2 at approximately 1 Torr and sprayed the produced F radicals R from the nozzle portion 20. The rest of the conditions were the same as the conditions of the first experiment explained above.

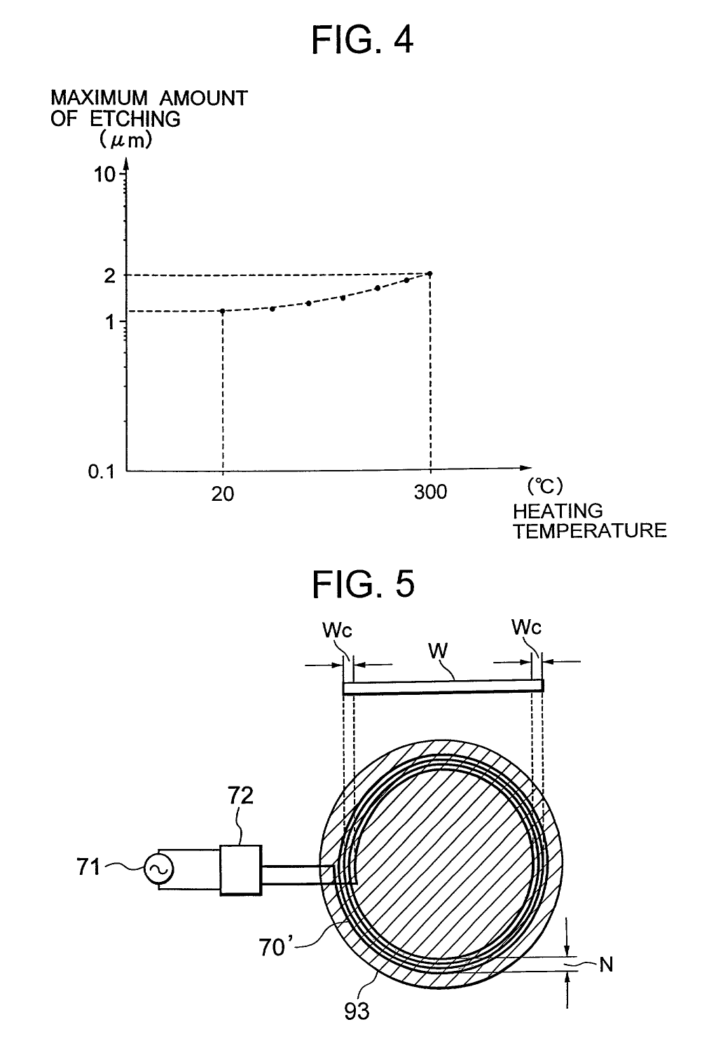

FIG. 4 is a graph of the results of the second experiment and shows the relationship between the heating temperature and maximum amount of etching.

SF₆ inherently has a large etching rate, so, as shown in FIG. 4, the amount of etching reaches as high as about 1.2 μm even at ordinary temperature. If the heating temperature of the silicon wafer W is raised, however, the amount of etching becomes even higher and reaches as high as about 2.0 μm at 300° C. Regardless of the fact that white or yellow deposit was observed on the surface of the silicon wafer W at ordinary temperature, however, when heated to 50° C., the deposit became thinner and when heated to 100° C., the deposit completely disappeared and the surface of the silicon wafer W became a mirror surface. Therefore, from the results of the experiment, it was learned that when using SF₆ gas under the above conditions, by setting the heating temperature of the silicon wafer W to at least 100° C., it is not only possible to obtain a large etching rate, but also possible to obtain a good mirror surface.

(Second Embodiment)

FIG. 5 is a schematic sectional view of essential portions of a local etching apparatus according to a second embodiment of the present invention.

In this embodiment, the shape of the heating wire of the wafer heating portion 7 differs from the shape of the heating wire 70 of the first embodiment.

That is, as shown in FIG. 5, the heating wire 70′ is wound in a ring along the outer circumference Wc of the silicon wafer W. The width N is set in accordance with the width of the outer circumference Wc of the silicon wafer W.

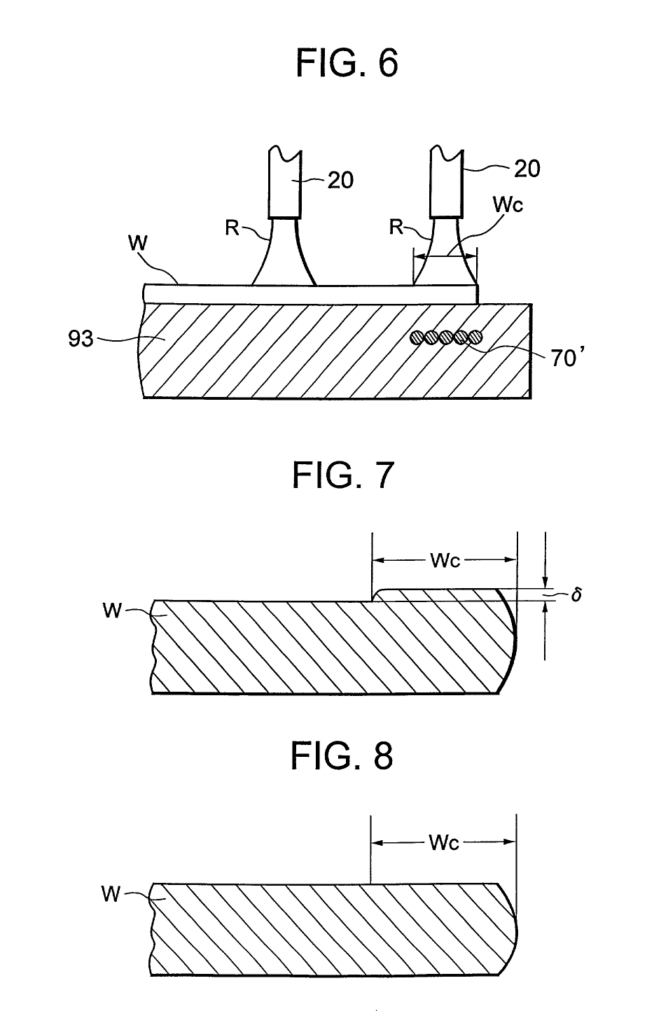

Due to this configuration, when the temperature of the heating wire 70′ is raised by the voltage regulator 72 of the wafer heating portion 7, the temperature of the outer circumference Wc of the silicon wafer W becomes higher than the temperature of the other portions. Therefore, as shown in FIG. 6, the etching rate when the nozzle portion 20 etches the outer circumference Wc of the silicon wafer W becomes larger than the etching rate when etching portions other than the outer circumference Wc. The etching rate of the outer circumference Wc of the silicon wafer W at the time of no heating, however, is smaller than the etching rate of other portions, so by heating so that the temperature of the outer circumference Wc becomes higher than the temperature of the other portions by exactly a predetermined temperature, it is possible to make the etching rate of the outer circumference Wc of the silicon wafer W substantially equal to the etching rate of the other portions. By adjusting the voltage regulator 72 to set the temperature of the heating wire 70 in this way, it is possible to etch the silicon wafer W as a whole flat.

The present inventors conducted the following experiment to provide evidence of this point.

In this experiment, in the same way as the first experiment in the above first embodiment, they adjusted the flow rates of the CF₄ gas and the O₂ gas to 600 sccm and 36 sccm, respectively, to feed a mixed gas comprised of 6 percent of O₂ with respect to CF₄ to the alumina discharge tube 2 at approximately 1 Torr and sprayed the produced F radicals R from the nozzle portion 20. They used, as a silicon wafer W, a silicon wafer W of a diameter of 200 mm and moved the nozzle portion 20 at a relative speed of 10 mm/s with respect to the silicon wafer W for the etching.

They performed the etching at ordinary temperature without operating the wafer heating portion 7, whereupon, as shown in FIG. 7, the outer circumference Wc remained thicker by exactly . compared with the other portions. The residual thickness . was about 0.1 μm.

Next, they set the width of the heating wire 70′ to 20 mm in accordance with the width N of the outer circumference Wc and heated the outer circumference Wc to 200° C. to make the temperature of the outer circumference Wc higher than the temperature of the other portions by exactly 25° C. to 30° C., whereupon, as shown in FIG. 8, the entire surface of the silicon wafer W became substantially flat. This shows that by making the heating temperature of the outer circumference Wc of the silicon wafer W higher than the temperature of the other portions by exactly 25° C. to 30° C., the etching rate of the entire surface of the silicon wafer W becomes substantially equal.

The rest of the configuration, mode of operation, and advantageous effects are similar to those of the above first embodiment, so descriptions thereof will be omitted. Note that when operating the local etching apparatus of this embodiment, the local etching method according to the aspect of the invention can be specifically executed.

The present invention is not limited to the above embodiments. Various modifications and changes are possible within the scope of the gist of the invention.

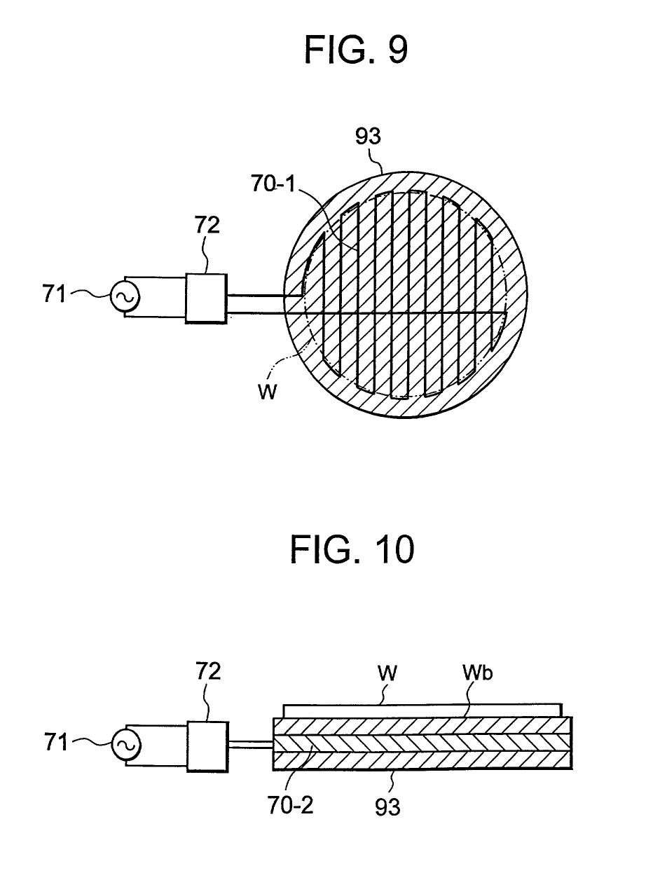

For example, in the first embodiment, use was made of a heating wire 70 bent in a spiral along the entire back surface Wb of the silicon wafer W, but as shown in FIG. 9, it is also possible to use a heating wire 70-1 bent in a grid along the entire back Wb of the silicon wafer W. Further, as shown in FIG. 10, it is possible to use a disk-shaped heating plate 702 of the same dimensions as the back Wb of the silicon wafer W.

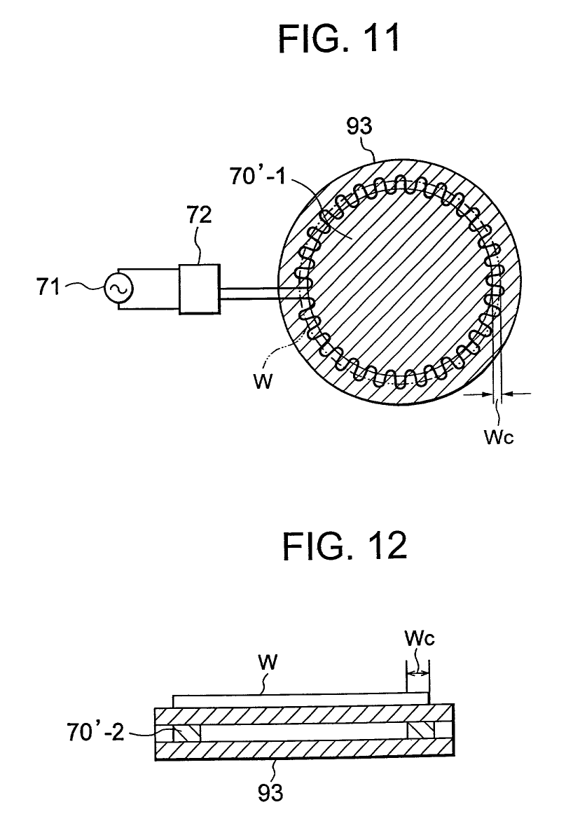

Further, in the second embodiment, use was made of a ring-shaped heating wire 70′ of a width corresponding to the outer circumference Wc of the silicon wafer W, but as shown in FIG. 11, it is also possible to use a heating wire 70′-1 bent in waves along the outer circumference Wc of the silicon wafer W. Further, as shown in FIG. 12, it is also possible to use a donut-shaped heating plate 70′-2 corresponding to the outer circumference Wc of the silicon wafer Wc.

Further, in the above embodiments, a wafer heating portion 7 for heating the heating wire 70 etc. by voltage was used as the heating means, but it is also possible to use an optical heating means for heating the silicon wafer W by irradiating infrared light or a laser beam to the front or back of the silicon wafer W.

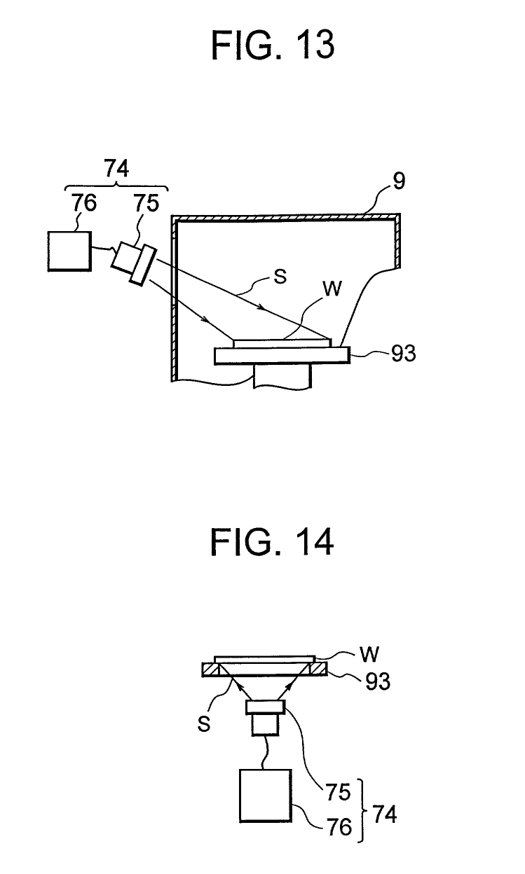

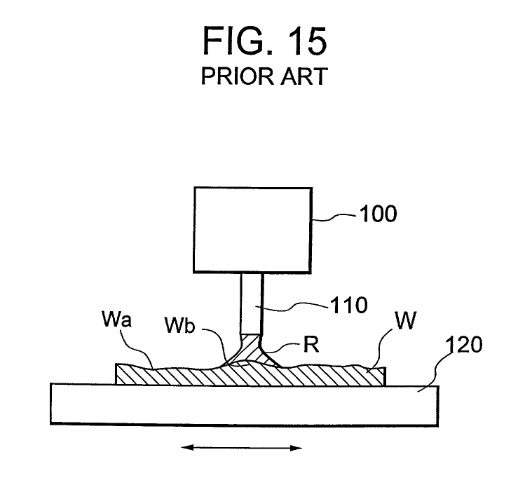

That is, as shown in FIG. 13, it is possible to constitute the wafer heating portion 74 by a known halogen heater 75 and power supply 76 and irradiate infrared light S from a not shown lamp of the halogen heater 75 through a window of the chamber 9 to the entire front of the silicon wafer W and thereby uniformly heat the entire surface of the silicon wafer W. Further, as shown in FIG. 14, it is possible to arrange a halogen heater 75 below the chuck 93 and irradiate infrared light S to substantially the entire surface of the back of the silicon wafer W. Further, it is possible to focus the infrared light S to a spot and irradiate it only at the outer circumference Wc of the silicon wafer W.

In the above embodiments, a mixed gas of CF₄ and O₂ and a mixed gas of SF₆ and O₂ were used as the plasma discharge gases, but it is also possible to use CF₄ or SF₆ gas alone. Further, it is also possible to use NF₃ (nitrogen trifluoride) gas instead of the CF₄ gas etc.

Further, in the above embodiments, an alumina discharge tube 2 was used as the discharge tube 2, but a sapphire discharge tube or a quartz discharge tube may also be used.

Further, in the above embodiments, a plasma generator 1 generating plasma by microwaves was used as the plasma generating means, but it may be any means able to produce radicals. For example, it is of course also possible to use a plasma generator using a high frequency to generate plasma and produce radicals and other various types of plasma generators.

As explained above in detail, according to the aspects of the invention, since the etching rate of the entire surface of the object to be etched is increased by uniformly heating the entire surface of the object to be etched, it is possible to improve the throughput. Further, since no white turbidity etc. occurs at the object to be etched even when using SF₆ gas, there is the superior effect that it is possible to ensure an excellent mirror surface at the front of the object to be etched.

Further, according to the aspects of the invention, since the etching rate of the outer circumference of the object to be etched and the etching rate of the other portions are made substantially equal, it is possible to etch the entire surface of the object to be etched by a uniform etching rate and as a result possible to improve the flatness of the object to be etched.

What is claimed is:

1. A local etching apparatus comprising:
a plasma generating means for causing plasma discharge of a predetermined gas in a discharge tube to produce radicals and spraying the radicals from a nozzle portion of the discharge tube toward a relatively thick portion present on the surface of an object to be etched;
a gas feeding means for feeding the predetermined gas to the discharge tube of said plasma generating means; and
a heating means for heating the object to be etched to a predetermined temperature.

2. A local etching apparatus as set forth in claim 1, wherein said heating means is designed to heat the entire object to be etched to a substantially uniform temperature.

3. A local etching apparatus as set forth in claim 2, wherein said heating means is provided with a electrical heating member arranged facing substantially the entire surface of the back of the object to be etched and capable of being raised in temperature in accordance with the voltage supplied and a voltage controller for controlling the voltage supplied to said electrical heating member.

4. A local etching apparatus as set forth in claim 3, wherein
said heating means is a heater; and
said electrical heating member is a heating wire bent into a spiral or grid along substantially the entire surface of the back of the object to be etched.

5. A local etching apparatus as set forth in claim 2, wherein said heating means is an optical heating means which irradiates infrared light or a laser beam on substantially the entire surface of the front or back of the object to be etched to heat the object to be etched.

6. A local etching apparatus as set forth in claim 1, wherein said heating means is designed to heat the object to be etched so that the temperature of the outer circumference of the object to be etched becomes higher than the temperature of the center of the object to be etched by exactly a predetermined temperature so as to make the etching rate of the outer circumference of the object to be etched and the etching rate of the rest of the portions of the object to be etched substantially equal.

7. A local etching apparatus as set forth in claim 6, wherein said heating means is provided with a electrical heating member arranged to face the outer circumference of the back of the object to be etched and capable of being raised in temperature in accordance with the voltage supplied and a voltage controller for controlling the voltage supplied to said electrical heating member.

8. A local etching apparatus as set forth in claim 7, wherein
said heating means is a heater; and
said electrical heating member is a electrical heating wire bent into a spiral or grid along the outer circumference of the back of the object to be etched.

9. A local etching apparatus as set forth in claim 6, wherein said heating means is an optical heating means which irradiates infrared light or a laser beam on the outer circumference of the front of the object to be etched to heat the object to be etched.

10. A local etching apparatus as set forth in claim 1, wherein the heating temperature of the object to be etched is a temperature in the range of from 20° C. to 300° C.

11. A local etching apparatus as set forth in claim 1, wherein
the object to be etched is a silicon wafer; and
the predetermined gas which the gas feeding means supplies to the discharge tube is a gas selected from the group consisting of carbon tetrafluoride gas, sulfur hexafluoride gas, nitrogen trifluoride gas and a mixed gas containing at least one of these gases.

12. A local etching method comprising:
a plasma generating step of causing plasma discharge of a predetermined gas in a discharge tube to produce radicals and spraying the radicals from a nozzle portion of the discharge tube;
a local etching step of making the nozzle portion of the discharge tube move relative to the surface of the object to be etched and locally etch a relatively thick portion present on the surface of the object to be etched by the radicals sprayed from the nozzle portion; and
a heating step of heating the object to be etched to a predetermined temperature.

13. A local etching method as set forth in claim 12, wherein said heating step is designed to heat the object to be etched so that the object to be etched as a whole becomes a substantially uniform temperature.

14. A local etching method as set forth in claim 12, wherein said heating step heats the object to be etched so that the temperature of the outer circumference of the object to be etched becomes higher than the temperature of the center of the object to be etched by exactly a predetermined temperature so as to make the etching rate of the outer circumference of the object to be etched and the etching rate of the rest of the portions of the object to be etched substantially equal.

15. A local etching method as set forth in claim 12, wherein said heating step heats the object to be etched to a temperature in the range of from 20° C. to 300° C.

16. A local etching method as set forth in claim 12, wherein
the object to be etched is a silicon wafer; and
the predetermined gas in the discharge tube in the plasma generating step is a gas selected from the group consisting of carbon tetrafluoride gas, sulfur hexafluoride gas, nitrogen trifluoride gas and a mixed gas containing at least one of these gases.
